(19) United States
(12) Patent Application Publication
(10) Pub. No.: US 2003/0132774 A1
(43) Pub. Date: Jul. 17, 2003

(54) Analogue signal testing system for integrated circuit

(76) Inventor: Te-Wei Chen, Hsinchu Hsien (TW)

Correspondence Address: J.C. Patents, Inc., 4 Venture, Suite 250, Irvine, CA, 92618, US

(21) Appl. No.: 10/047,755

(22) Filed: Jan. 14, 2002

(51) Int. Cl. G01R 31/26

(52) U.S. Cl. 324/765; 324/751

(57) ABSTRACT

A system and method for testing signal transmission within an integrated circuit. The testing system includes a test-signal output device and a test-signal receiver. To test the integrated circuit, the test-signal output device transmits testing signals to the integrated circuit so that the integrated circuit produces some resulting test signals. The test-signal receiver picks up the resulting test signals from the integrated circuit for further analysis.

### BACKGROUND OF THE INVENTION

1. Field of Invention

The present invention relates to a signal testing system for an integrated circuit. More particularly, the present invention relates to a system for testing internal circuit signals within an integrated circuit.

2. Description of Related Art

FIG. 1 is a schematic diagram showing the perspective view of a conventional electron beam integrated circuit testing system. As shown in FIG. 1, the system comprises a test-signal output device 10, a vacuum switch 11 and an electron beamer 14. To test an integrated circuit 12, the integrated circuit 12 package is placed on the test-signal output device 10. Appropriate test signals are fed into the integrated circuit 12 so that the integrated circuit 12 may operate accordingly. In the meantime, the electron beamer 14 generates an electronic beam that aims at a particular section of the integrated circuit 12 to be tested. To minimize the effect of air on the electron beam, the vacuum switch 11 is switched on to produce a vacuum inside the testing system. Because magnetic fields are produced inside the integrated circuit package 12 after receiving some test signals from the test-signal output device 10, the electron beam coming from the electron beamer 14 is deflected by the magnetic field resulting in a reflected beam at a different angle. By gauging the angle of the reflected beam, signaling inside the particular section of the integrated circuit 12 can be assessed. However, such a system not only demands the deployment of expensive equipment including an electron beamer and associated monitors, to serve as an input and measuring device, but also requires the creation of a vacuum environment for the passage of the electron beam. Moreover, due to the complicated system connection and coordination, the system is hard to operate as well.

FIG. 2 is a schematic diagram showing the perspective view of a conventional pin-probe testing system for an integrated circuit. As shown in FIG. 2, the system includes a signal generator 18 and a waveform display device 26. To begin a testing, an integrated circuit 24 is placed on a desk 16. Appropriate testing signals are transmitted from the signal generator 18 to the integrated circuit 24 via a set of testing probes 20 and 22. The integrated circuit 24 functions accordingly. The waveform display device 26 picks up resulting signals from the integrated circuit 24 via another set of probing pins 28 and 30. The waveform display device checks the received signals and determines if the integrated circuit 24 functions as expected. In general, this type of testing system uses testing probes to transfer testing signal from signal generator to the integrated circuit. Since complicated wiring connections must be established before the test, time and manpower is wasted.

### SUMMARY OF THE INVENTION

Accordingly, one object of the present invention is to provide a time and cost saving system for testing operating signals inside an integrated circuit

To achieve these and other advantages and in accordance with the purpose of the invention, as embodied and broadly described herein, the invention provides a system for testing operating signal inside an integrated circuit. The testing system includes a test-signal output device and test-signal receiver. The test-signal output device feeds testing signals into the integrated circuit. The integrated circuit generates a set of result signals. The test-signal receiver picks up the result signals from the integrated circuit through a set of test probes.

This invention also provides a method of testing signal transmission inside an integrated circuit. First, a test-signal output device and a test-signal receiver are provided. The test-signal output device generates a set of test signals and transmits to the integrated circuit. The test-signal receiver then picks up the resulting signal generated by the integrated circuit.

This invention also provides a system and a method for testing analogue signal transmission inside an integrated circuit. The system has a test-signal output device. The test-signal output device transmits a set of testing signals to the integrated circuit without the need for having a complicated wiring setup. Consequently, time and manpower is saved. In addition, using a test-signal output device instead of a conventional electron beamer to conduct the test, equipment budget is greatly reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic diagram showing the perspective view of a conventional electron beam integrated circuit testing system;

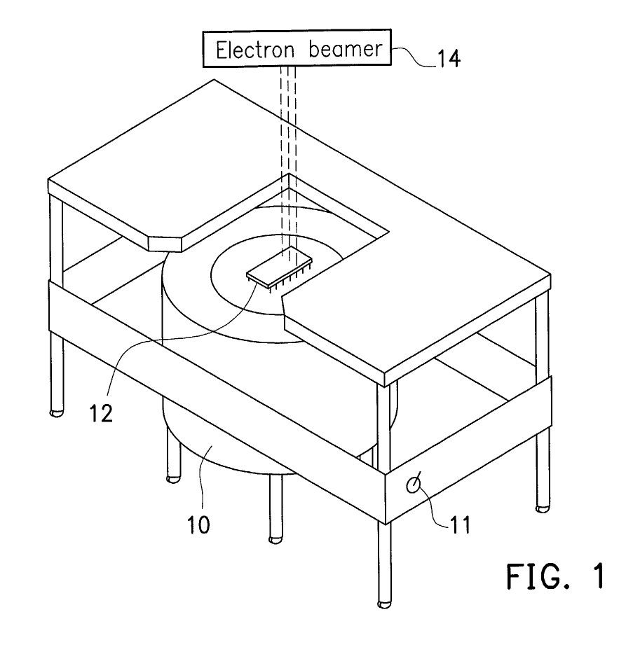

FIG. 2 is a schematic diagram showing the perspective view of a conventional pin-probe testing system for an integrated circuit;

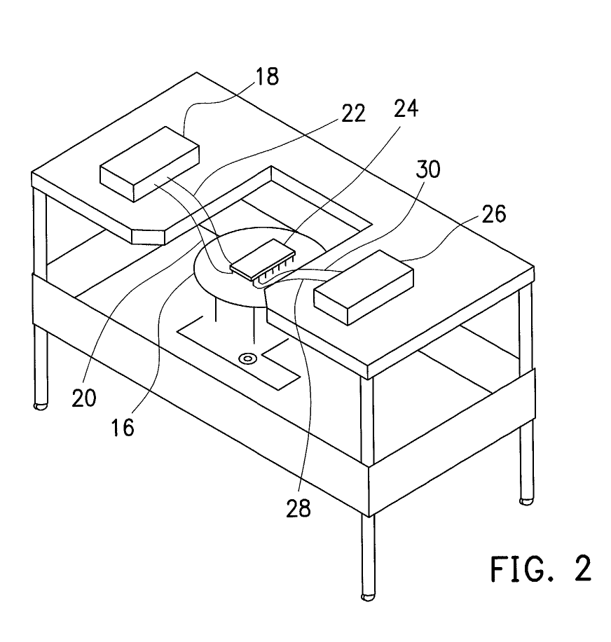

FIG. 3 is a schematic diagram showing the perspective view of a system for testing analogue signal transmission inside an integrated circuit according to this invention; and

FIG. 4 is a flow chart showing the steps for testing signaling transmission within an integrated circuit according to this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

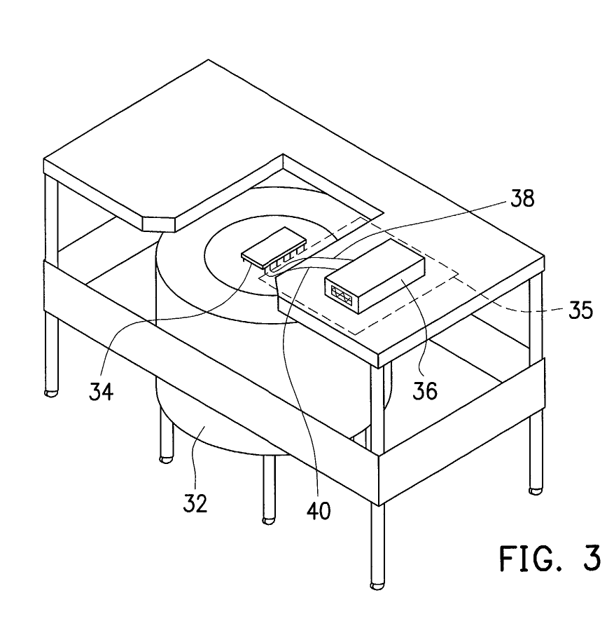

FIG. 3 is a schematic diagram showing the perspective view of a system for testing analogue transmission inside an integrated circuit according to this invention. As shown in FIG. 3, the testing system includes a test-signal output device 32 and a test-signal receiver 35. To test an integrated circuit 34, the test-signal output device 32 transmits a set of testing signals to the integrated circuit 34. The integrated circuit 34 operates normally to produce a set of resulting signals. The test-signal receiver 35 picks up the set of resulting signals from the integrated circuit 34 and checks for any abnormality. The test-signal output device 32 is, for example, a testing station.

The test-signal receiver 35 has a set of testing probes (38 and 40) and a waveform display device 36. The waveform display device 36 is coupled to the testing probes 38 and 40. After sending a set of testing signals to the integrated circuit 34, the testing probes 38 and 40 are made to contact output terminals of the particular section of the integrated circuit 34 to be tested and hence obtain the resulting test signals. In general, the output terminal of an integrated circuit is coated with a passivation layer. Hence, holes are normally punched by aiming an ion beam at probe contact positions in the passivation layer so that the testing probes may form good contact with the respective output terminals. The waveform display device 36 picks up test signals from the integrated circuit 34 and generates waveforms on a display screen. Quality of the integrated circuit 34 is assessed according to the signal waveform displayed on the screen.

In a testing system that uses an electron beam to assess the working conditions of the integrated circuit 34, besides the test-signal output device 32, an electron beamer 14 must be incorporated into the testing system. To test the integrated circuit 34, the electron beamer 14 generates an electron beam and aims the beam at a particular section of the integrated circuit 34 where testing is required. Furthermore, to reduce any interference of the electron beam with air, air needs to be evacuated. Hence, the testing system requires a vacuum system as well. When a set of testing signals is passed from the signal-test output device 32 to the integrated circuit 34, a magnetic field is generated inside the integrated device 34. The magnetic field deflects the electron beam aiming at the integrated circuit 34 causing a different angle of reflection. Hence, working conditions of the integrated circuit 34 can be assessed according to the angle of reflection of the electron beam.

In a testing system that uses testing probes to assess the working condition of the integrated circuit 34, a conventional system uses a signal generator 18 to transmit testing signals to the integrated circuit 34 via a set of testing probes (20 and 22). If the integrated circuit 34 demands ten testing signals to operate, ten testing probes are used to link up the signal generator 18 and the integrated circuit 34. Hence, wiring connections are time-consuming and complicated. In this invention, the signal output device 32 generates and transmits testing signals to the integrated circuit 34 directly so that complicated wiring connections are avoided.

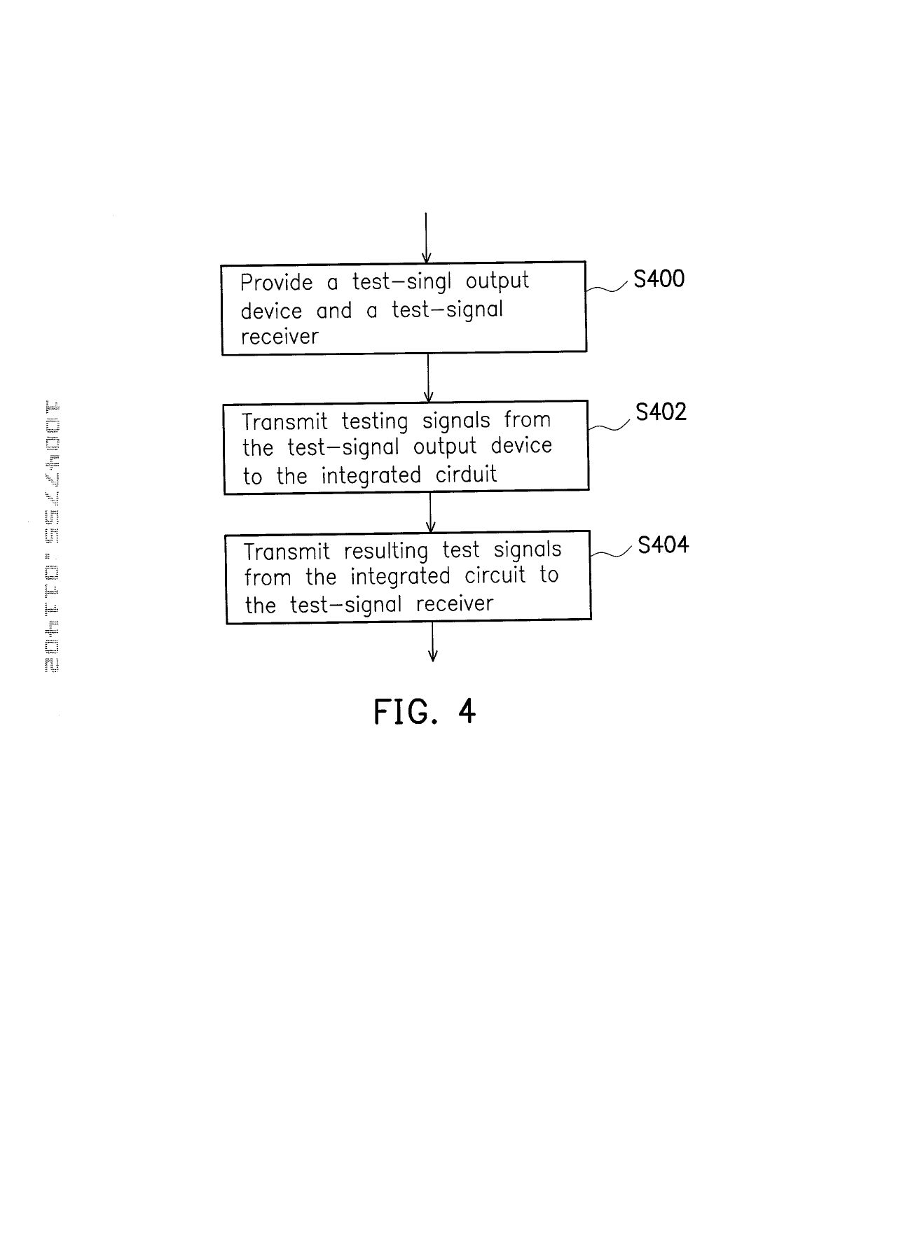

FIG. 4 is a flow chart showing the steps for testing signaling transmission within an integrated circuit according to this invention. To test an integrated circuit, the following steps are conducted in sequence. In step S400, a test-signal output device and a test-signal receiver are provided. In step S402, the test-signal output device transmits a set of testing signals to the integrated circuit triggering operations within the integrated circuit. In step S404, the test-signal receiver picks up a set of result test signals from the integrated circuit and uses the resulting test signals to assess quality level of the integrated circuit.

In conclusion, one major advantage of this invention is the utilization of a signal-test output device to transmit test signals directly to the integrated circuit so that complicated wiring is unnecessary. Another advantage is the use of a cheaper test-signal output device to replace conventional expensive electron beam equipment

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A system for transmission signals inside an integrated circuit, comprising:
a test-signal output device for sending a plurality of testing signals to the integrated circuit so that the integrated circuit can generate a plurality of resulting test signals; and
a test-signal receiver for picking up the resulting test signals, wherein the test-signal receiver at least includes a set of testing probes for receiving the resulting test signals.

2. The system of claim 1, wherein the test-signal receiver further includes:
a waveform display device coupled to the testing probes for receiving the resulting test signals and displaying the waveform of the test signals on a screen.

3. The system of claim 1, wherein the test-signal output device is a testing station that holds the integrated circuit and passes testing signal into the integrated circuit.

4. A method of testing transmission signal inside an integrated circuit, comprising the steps of:
providing a test-signal output device;
providing a test-signal receiver;
transmitting a plurality of testing signals generated by the test-signal output device to the integrated circuit; and
transmitting the test signals that result from the integrated circuit to the test-signal receiver.
